(19) United States
(12) Patent Application Publication
(10) Pub. No.: US 2011/0023936 A1
(43) Pub. Date: Feb. 3, 2011

(54) Concentrating unit of a photovoltaic apparatus

(75) Inventors: Hwa-Yuh Shin, Longtan Shiang (TW); Huug-zen Kuo, Longtan Shiang (TW); Hung-Sheng Chiu, Longtan Shiang (TW)

Correspondence Address: Jackson Intellectual Property Group PLLC, 106 Starvale Lane, Shipman, VA, 22971, US

(73) Assignee: ATOMIC ENERGY COUNCIL - INSTITUTE OF NUCLEAR ENERGY RESEARCH, Taoyuan (TW)

(21) Appl. No.: 12/076,250

(22) Filed: Mar. 14, 2008

(51) Int. Cl. H01L 31/052

(52) U.S. Cl. 136/246

(57) ABSTRACT

A concentrating unit includes a concentrator and two supporting elements. The concentrator includes an incident end from which the sunlight goes into the concentrator, an exit end from which the sunlight leaves the concentrator and a reflective surface between the incident end and the exit end for the reflecting and hence concentrating the sunlight while the sunlight is traveling through the concentrator. Each of the supporting elements includes an upright section extended from the concentrator and a horizontal section extended from the upright section for attachment to a solar cell module.

### FIELD OF THE INVENTION

The present invention relates to a concentrating unit for a photovoltaic apparatus and, more particularly, to a concentrating unit including a concentrator and two supporting elements for firmly attaching the concentrator on a solar cell module.

### DESCRIPTION OF THE RELATED ARTS

Because of the rapid growth of demand in solar energy and high power transfer efficiency, the techniques to collect more power onto solar cell become more prominent. Hence some concentrators have been brought out to capture more sunlight onto solar cells so that the electricity converted from the sunlight by the solar cells will be higher.

Referring to FIG. 4, a conventional concentrator 5 includes an incident end 51, an exit end 52 and a reflective cone surface 53 between the incident end 51 and the exit end 52 which is smaller than incident end 51. When in use, the concentrator 5 is settled toward to the sun so that the sunlight 61 goes into the concentrator 5 through the incident end 51 and leaves the concentrator 5 from the exit end 52. The reflective surface 53 could collect light which is not normal incident onto solar cell. The concentrator 5 is attached to a solar cell module by adhesion so that the exit end 52 is connected directly to a solar cell of the solar cell module. However, the attachment by adhesion is not reliable and could easily be detached from the solar cell module because of vibration or rattling.

The present invention is therefore intended to obviate or at least alleviate the problems encountered in prior art.

### SUMMARY OF THE INVENTION

The primary objective of the present invention is to provide a reliable concentrating unit.

To achieve the foregoing objective, the concentrating unit includes a concentrator and two supporting elements. The concentrator includes an incident end from which the sunlight goes into the concentrator, an exit end from which the sunlight leaves the concentrator and a reflective surface between the incident end and the exit end for the reflecting to help concentrate the sunlight. Each of the supporting elements includes an upright section extended from the concentrator and a horizontal section extended from the upright section for attachment to a solar cell module.

Other objectives, advantages and features of the present invention will become apparent from the following description referring to the attached drawings.

### BRIEF DESCRIPTION OF THE DRAWINGS

The present invention will be described via the detailed illustration of two embodiments referring to the drawings.

FIG. 1 is an exploded view of a concentrator for a photovoltaic apparatus according to the first embodiment of the present invention.

FIG. 2 is a perspective view of a concentrator for a photovoltaic apparatus shown in FIG. 1.

FIG. 3 is a partial view of a concentrator for a photovoltaic apparatus according to the second embodiment of the present invention.

FIG. 4 is a perspective view of a conventional concentrator for a photovoltaic apparatus.

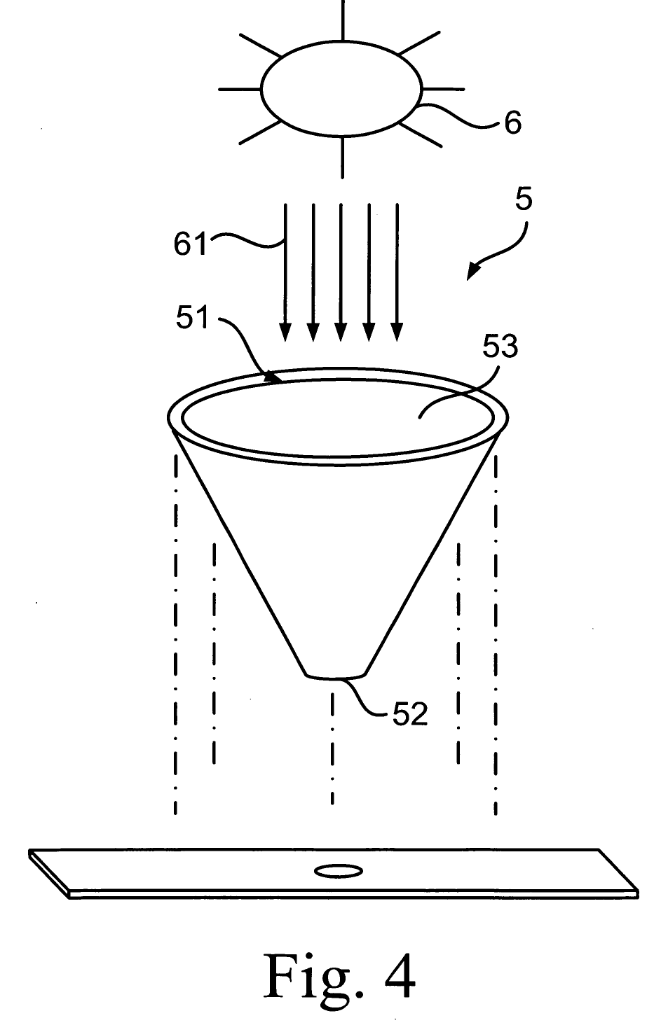

### DETAILED DESCRIPTION OF EMBODIMENT

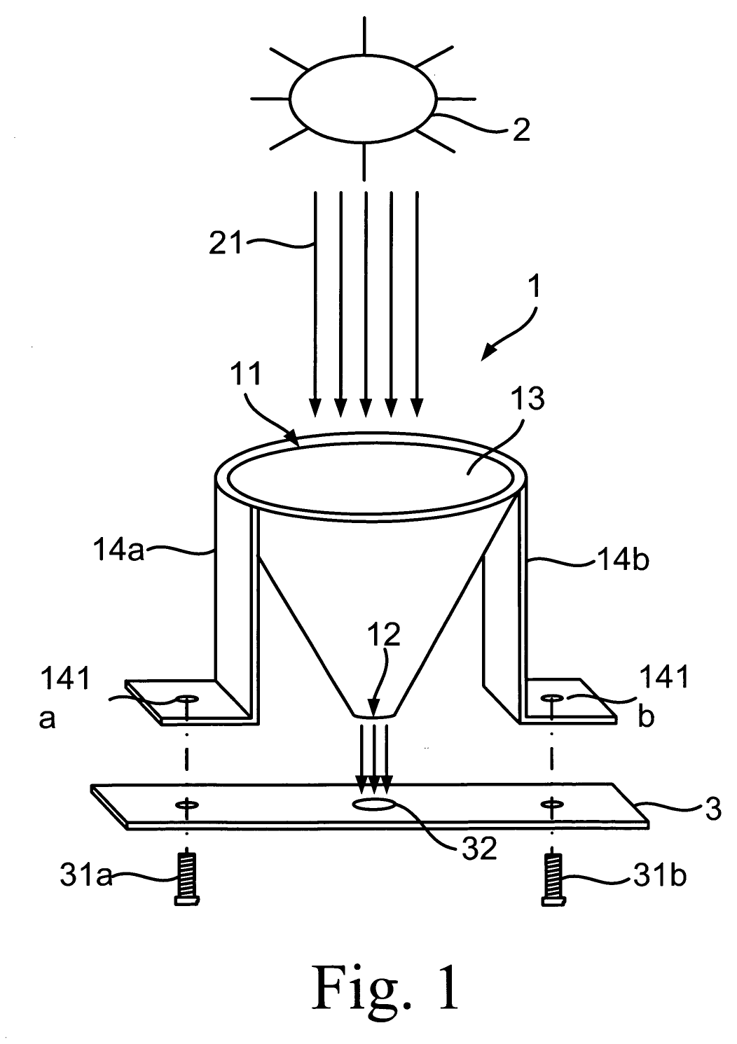

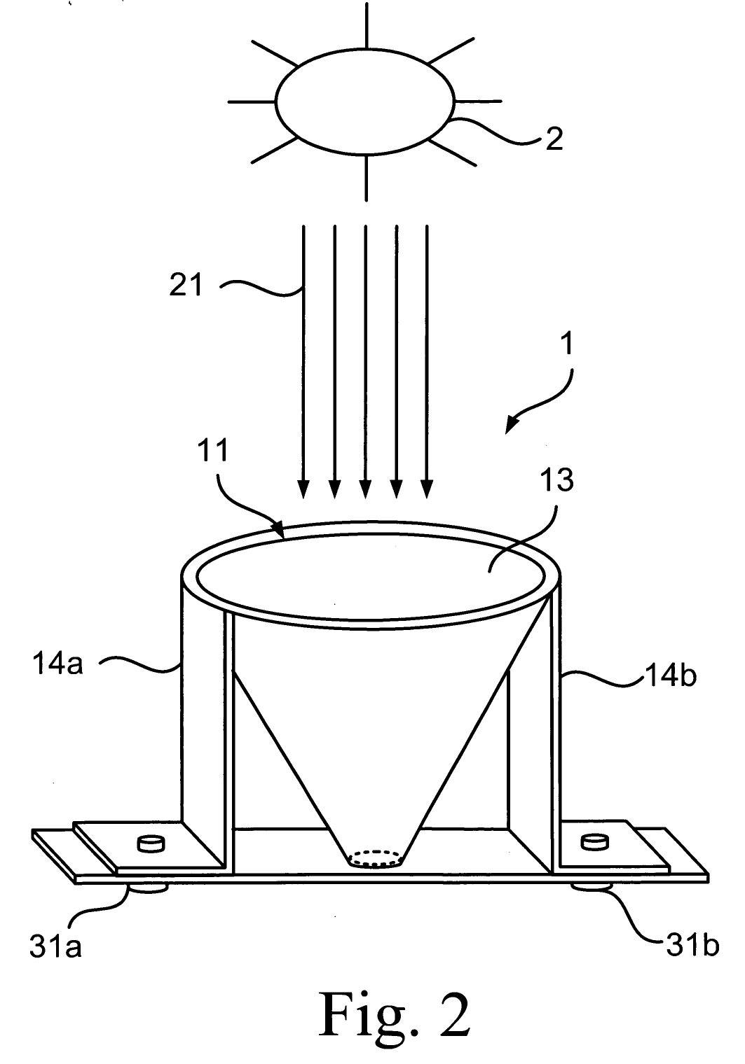

Referring to FIGS. 1 and 2, there is shown a concentrating unit for a photovoltaic apparatus according to a first embodiment of the present invention. The concentrating unit includes a concentrator 1 and two supporting elements 14a and 14b for firmly attaching the concentrator 1 on a solar cell module 3.

The concentrator 1 includes an incident end 11, an exit end 12 and a reflective surface 13 between the incident end 11 and the exit end 12. The concentrator 1 is in the form of a conical frustum. In use, the incident end 11 is right toward to the sun 2 so that the sunlight 21 goes into the concentrator 1 from the incident end 11 and leaves the concentrator 1 from the exit end 12.

The reflective surface 13 reflects the indirect portion of sunlight 21 as the sunlight 21 travels through the concentrator 1. Therefore, the intensity of the sunlight 21 is higher at the exit end 12 than at the incident end 11.

The supporting elements 14a and 14b are preferably formed together with the concentrator 1. The supporting elements 14a and 14b may however be secured to the concentrator 1 according to another embodiment. The supporting elements 14a and 14b are located opposite to each other. The supporting elements 14a and 14b are L-shaped. That is, each of the supporting elements 14a and 14b includes an upright section extended from the concentrator 1 and a horizontal section transversely extended from the upright section. A screw holes 141a and 141b are defined in the horizontal section of the supporting element 14a and 14b, respectively.

Threaded bolts 31a and 31b are driven into the screw holes 141a and 141b through two apertures defined in the solar cell module 3, respectively. Thus, the concentrator 1 is firmly supported on the solar cell module 3. The exit end 12 is located right above a solar cell 32 of the solar cell module 3 so that the concentrated sunlight 21 is directed to the solar cell 32.

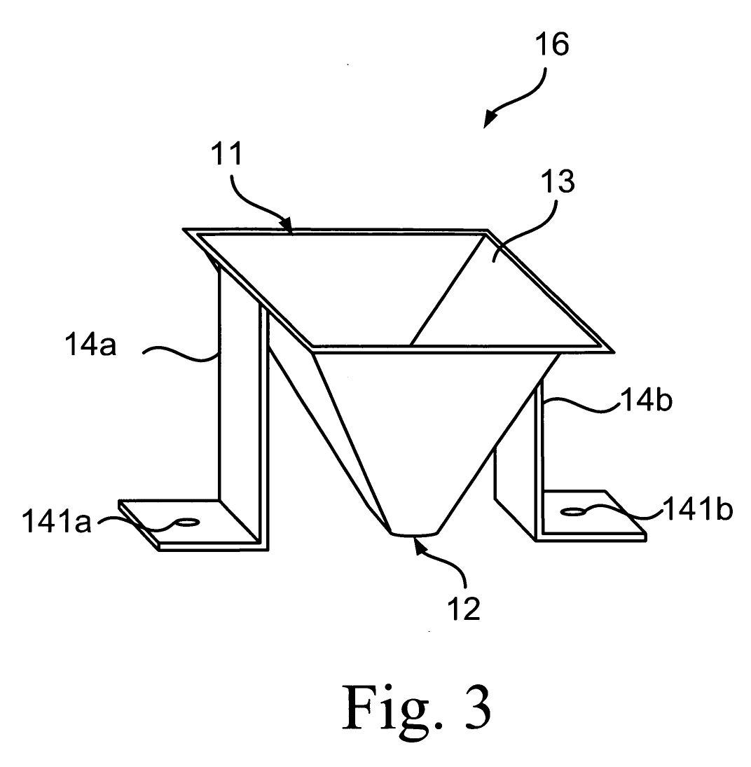

Referring to FIG. 3, there is shown a concentrating unit according to a second embodiment of the present invention. The second embodiment is identical to the first embodiment except for a concentrator 16 instead of the concentrator 1. The concentrator 16 is in the form of quadrilateral frustum.

The position of the concentrator 1 or 16 relative to the solar cell module 3 is retained during vibration or rattling. Thus, the distance between the exit end 12 and the solar cell 32 is retained, and the exit end 12 is always aligned with the solar cell 32. Therefore, the concentrated sunlight 21 won't be leaked, thus ensuring appropriate throughput of electricity converted from the concentrated sunlight 21.

The present invention has been described via the detailed illustration of the embodiments. Those skilled in the art can derive variations from the embodiments without departing from the scope of the present invention. Therefore, the embodiments shall not limit the scope of the present invention defined in the claims.

1. A concentrating unit comprising:
a concentrator comprising:
an incident end from which the sunlight goes into the concentrator;
an exit end from which the sunlight leaves the concentrator; and
a reflective surface between the incident end and the exit end for the reflecting and hence concentrating the sunlight while the sunlight is traveling through the concentrator; and
two supporting elements each comprising:
an upright section extended from the concentrator; and
a horizontal section extended from the upright section for attachment to a solar cell module.

2. The concentrating unit according to claim 1, wherein the concentrator is in the form of a conical frustum.

3. The concentrating unit according to claim 1, wherein the concentrator is in the form of a quadrilateral frustum.

4. The concentrating unit according to claim 1, wherein the incident end is larger than the exit end.

5. The concentrating unit according to claim 1, wherein each of the supporting elements comprises a screw hole in the horizontal section for receiving a threaded bolt driven through the solar cell module.
